(19) United States
(12) Patent Application Publication
(10) Pub. No.: US 2026/0100676 A1
(43) Pub. Date: Apr. 9, 2026

(54) SOLID-STATE, ELECTRONICALLY CONTROLLED BROADBAND THZ MODULATOR VIA ORGANIC ELECTROCHEMICAL DEVICE

(71) Applicant: The Trustees of Princeton University, Princeton, NJ (US)

(72) Inventors: Jonathan Scott, Plainsboro, NJ (US); Barry Rand, Princeton, NJ (US)

(73) Assignee: The Trustees of Princeton University, Princeton, NJ (US)

(21) Appl. No.: 19/349,060

(22) Filed: Oct. 3, 2025

Related U.S. Application Data
(60) Provisional application No. 63/703,293, filed on Oct. 4, 2024.

(51) Int. Cl. H03C 7/02; G02F 2/00; H01G 9/028; H01G 9/048; H01G 9/20; H04L 27/04

(52) U.S. Cl. CPC H03C 7/025; H01G 9/028; H01G 9/048; H01G 9/2009; H01G 9/2018; G02F 2/008; G02F 2203/13; H04L 27/04

(57) ABSTRACT

In various aspects, a device for reversibly modulating electromagnetic radiation may be provided. The device may include a base substrate. The device may include a patterned metal layer disposed over the base substrate. The patterned metal layer may include a plurality of electrodes separated by a gap and at least one additional metal pattern separated from the plurality of electrodes. The gap may define an active area through which radiation is passed. The device may include an organic layer disposed over at least the plurality of electrodes, and base substrate, and within the gap. The organic layer may include a conducting polymer. The device may include an ion gel disposed over the conducting polymer, the patterned metal layer, and the base substrate. The device may be configured to allow ions from the ion gel layer to transport into the conducting polymer.

### CROSS-REFERENCE TO RELATED APPLICATIONS

The present application claims priority to U.S. Provisional Patent Application 63/703,293, filed Oct. 4, 2024, the contents of which are incorporated by reference herein in its entirety.

### TECHNICAL FIELD

The present disclosure is drawn to devices, systems and methods for reversibly modulating electromagnetic radiation.

### BACKGROUND

This section is intended to introduce the reader to various aspects of the art, which may be related to various aspects of the present disclosure that are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Wireless systems for imaging, sensing, and communications continue to expand into higher frequency bands for improved bandwidth, resolution, directionality, and other benefits. In this context, the THz regime (from 0.1 to 10 THz) has recently gained attention. However, THz radiation presents unique challenges regarding the modulation and reconfigurability that are needed for many device applications. The so-called “THz gap” refers to the nascent state of development for the generation and manipulation of THz radiation. The necessary picosecond timescales place stringent requirements on the operation of THz devices that render conventional materials, and fabrication approaches less effective at higher frequencies. Consequently, most research on devices for the manipulation of THz radiation, such as 2D systems or periodic structures/metamaterials, relies on novel materials and complex fabrication techniques. Such approaches present additional challenges to solving the THz gap in scalability, reproducibility, and integration with existing technologies, hindering their widespread adoption. As such, there is an increasing desire for devices which address the THz gap.

### BRIEF SUMMARY

Various deficiencies in the prior art are addressed below by the disclosed devices, systems, and methods for reversibly modulating electromagnetic radiation.

In various aspects, a device for reversibly modulating electromagnetic radiation may be provided. The device may include a base substrate. The device may also include a patterned metal layer disposed over the base substrate. The patterned metal layer may include a plurality of electrodes separated by a gap and at least one additional metal pattern separated from the plurality of electrodes. The gap may define an active area through which radiation is passed. The patterned metal layer may either or additionally include one or more porous or incomplete metal electrodes. The porous or incomplete metal electrodes may include voids or gaps defining one or more active areas through which radiation may be passed. The device may also include an organic layer disposed over at least the plurality of electrodes, the one or more porous or incomplete metal electrodes, and the base substrate. Within the gap, the organic layer may include a conducting material (e.g., a polymer). The device may also include an ion gel layer disposed over the conducting material, the patterned metal layer, and the base substrate. The device may be configured to allow ions from the ion gel layer to transport into the conducting material, doping or de-doping the organic layer, when a voltage is applied to at least one electrode of the plurality of electrodes.

In some embodiments, the conducting material may be a conducting polymer. The conducting polymer may be conducting polythiophene. The conducting polythiophene may be polystyrene sulfonate (PEDOT:PSS). The conducting polythiophene may be pgBTTT.

In some embodiments, the conducting material may be a conducting small molecular weight organic material.

In some embodiments, the patterned metal layer may have a thickness of at least 50 nm. The patterned metal layer may have a thickness of 50 nm-500 nm.

In some embodiments, the active area may be at least 0.25 cm² in cross-sectional area in a plane parallel to a surface of the patterned metal layer. The active area may be 0.25 cm²-0.5 cm² in cross-sectional area in a plane parallel to a surface of the patterned metal layer.

In some embodiments, the one or more porous or incomplete metal electrodes may include one or more metal nanowire meshes.

In various aspects, a system may be provided. The system may include a device as described herein. The system may also include a detector disposed along a transmission path of one or more wavelengths of radiation from a radiation source through the active area of the device to the detector.

In some embodiments, the system may further include the radiation source. The system may further include a controller operably coupled to the device. The controller may be configured to control application of a voltage to the device.

In some embodiments, when a voltage is applied to the device, the voltage may be constant. When a voltage is applied to the device, the voltage may vary over time. When a voltage is applied to the device, the voltage may be repeatedly switched between each of the plurality of electrodes.

In some embodiments, polarity of an applied gate voltage may be periodically reversed.

In some embodiments, the detector may be configured to measure at least one THz wavelength of radiation. The at least one THz wavelength of radiation may be measured in a direction normal to a surface of the organic layer.

In various aspects, a method for reversibly modulating electromagnetic radiation may be provided. The method may include directing radiation from a radiation source towards an active area of a device as described herein. The method may also include applying a voltage to the device, modulating conductivity of material in the active area.

In some embodiments, the modulation may be an increase in power of the radiation at one or more wavelengths relative to the power of radiation prior to passing through the active area. The modulation may be a decrease in power of the radiation at one or more wavelengths relative to the power of radiation prior to passing through the active area.

Additional objects, advantages, and features of the present disclosure will be set forth in part in the description which follows, and in part will become apparent to those skilled in the art upon examination of the following or may be learned by practice of the present disclosure. The objects and advantages of the present disclosure may be realized and attained by means of the instrumentalities and combinations particularly pointed out in the appended claims.

### BRIEF DESCRIPTION OF FIGURES

The accompanying drawings, which are incorporated in and constitute a part of this specification, illustrate embodiments of the present disclosure and, together with a general description of the present disclosure given above, and the detailed description of the embodiments given below, serve to explain the principles of the present disclosure.

FIG. 1 shows a cross-sectional view of an embodiment of a device for reversibly modulating electromagnetic radiation.

FIG. 2 shows an exploded view of an embodiment of a device for reversibly modulating electromagnetic radiation.

FIG. 3 shows a flow diagram of an embodiment of a method for reversibly modulating electromagnetic radiation.

FIG. 4 shows a diagram illustrating concurrent DC conductivity, THz, and UV-Vis-NIR optical measurements.

FIG. 5 shows a cross-sectional view of another embodiment of a device for reversibly modulating electromagnetic radiation.

FIG. 6A shows a graphical representation of optical absorbance demonstrating PEDOT reduction upon application of a positive gate bias.

FIG. 6B shows a graphical representation of THz transmission change, demonstrating up to 9 dB (or 87.5%) modulation depth.

FIG. 6C shows a graphical representation of conductivity derived from THz or DC measurement.

FIG. 6D shows a graphical representation of pgBTTT optical absorption data.

FIG. 6E shows a graphical representation of a demonstration of accumulation mode behavior in pgBTTT via THz damping upon reverse bias, achieving up to ˜5.5 dB or 72% modulation depth.

FIG. 6F shows a graphical representation of a calculation and comparison of THz/DC pgBTTT conductivity.

FIGS. 7A-7F show a graphical representation of concurrent switching compared between DC, THz, and optical measurements.

FIGS. 8A-8C show a graphical representation of depletion mode devices with the upper and lower envelope signals of the PEDOT:PSS THz transmission taken over long-term switching.

FIG. 9A shows a graphical representation of the difference in the upper and lower envelopes in dB, plotted vs. time.

FIG. 9B shows a graphical representation of transmission behavior of the PEDOT:PSS depletion mode devices under continuous bias.

FIGS. 10A-10C show a graphical representation of multispectral switching behavior of pgBTTT-based accumulation mode devices.

FIGS. 11A-11C show a graphical representation of long-term switching behavior for accumulation mode devices.

FIG. 12 shows a graphical representation of long-term biasing tests of accumulation mode devices.

It should be understood that the appended drawings are not necessarily to scale, presenting a somewhat simplified representation of various features illustrative of the basic principles of the present disclosure. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the present disclosure. It will thus be appreciated that those skilled in the art will be able to devise various arrangements that, although not explicitly described or shown herein, embody the principles of the present disclosure and are included within its scope. Furthermore, all examples recited herein are principally intended expressly to be only for illustrative purposes to aid the reader in understanding the principles of the present disclosure and the concepts contributed by the inventor(s) to furthering the art and are to be construed as being without limitation to such specifically recited examples and conditions. Additionally, the term, “or,” as used herein, refers to a nonexclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the claims. Moreover, some statements may apply to some features but not to others. Those skilled in the art and informed by the teachings herein will realize that the present disclosure is also applicable to various other technical areas or embodiments.

The ongoing push toward higher frequencies and the concomitant bandwidths required for next-generation communications systems, biomedical diagnostics, imaging and spectroscopic systems, and other technologies necessitate new paradigms of materials and devices. The ability to dynamically control the transmission of frequencies is of critical need for modulation and reconfigurability of GHz to THz devices. Active THz modulators and switches capable of achieving large bandwidths are an ongoing area of research. Current technologies include metamaterials, optically and electrically gated semiconductor devices, as well as devices based on 2D materials such as graphene. However, all such devices require specialized design and fabrication techniques, hindering ease of use, scalability and integration into THz systems.

Conjugated-polymer-based electronic devices such as solar cells and light-emitting devices have showcased the diverse capabilities of this material class, with the added benefit of facile processing and fabrication. One such area of active conjugated polymer research is in organic electrochemical transistors (OECTs) which have shown promise in emerging areas of bioelectronics. The channel layer of such transistors consists of an organic mixed ionic-electronic conductor (OMIEC), the conductivity of which can be modulated by the application of a small external bias to an adjacent electrolyte, resulting in ionic injection into the bulk of the channel and consequent stabilization of charge transport in the channel. The DC conductivity change has also demonstrated effects in higher frequency regimes. Traditional electrolytes in OECTs include aqueous ionic species such as NaCl diluted in water. Recent advances in electrolyte materials include ionic liquids or solid-state electrolytes consisting of ionic species contained in a structured polymer network through which they can migrate.

The modulation of material properties beyond DC conductivity based on redox chemistry is illustrated by the use of OMIECs in electrochromic devices (ECDs). One of the most common OMIECs used in both OECTs and ECDs is a combination of poly(3,4-ethylenedioxythiophene) (PEDOT) and polystyrene sulfonate (PSS), or PEDOT:PSS. The PEDOT cation is an excellent ionic and electronic conductor, with the PSS anion acting as a counterion to stabilize holes in the p-type PEDOT phases. Upon application of a positive bias to an adjacent electrolyte, cations migrate into the PEDOT:PSS channel layer, compensating the PSS anions, decreasing hole concentration and thus conductivity. This also results in a change in the color of the PEDOT:PSS channel due to the differing absorption characteristics of the neutral and charged PEDOT species, known as electrochromic switching. Since the device is considered conductive or “ON” without an external bias, its operation is considered to be in depletion mode. Similar effects can occur in accumulation mode devices, where anions migrate into the bulk of a non-conductive polymer back-bone under bias, stabilizing holes in the backbone and increasing conductivity in the channel. Such processes are reversible upon removal of the bias, as ions are allowed to migrate back into the electrolyte.

Drawing inspiration from the conductivity modulation capability of OECTs and optical switching capabilities of electrochromic devices, presented herein is a device structure capable of modulating incident THz radiation upon application of an external voltage bias.

### System Overview

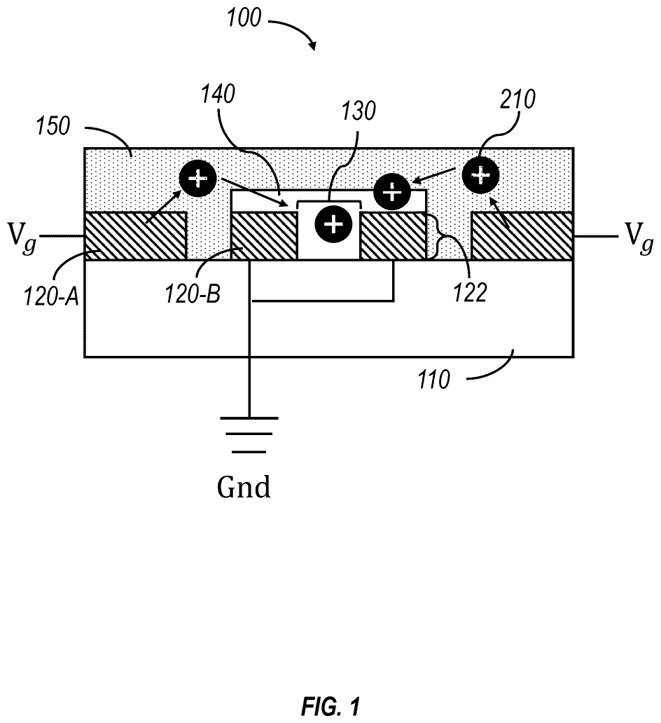

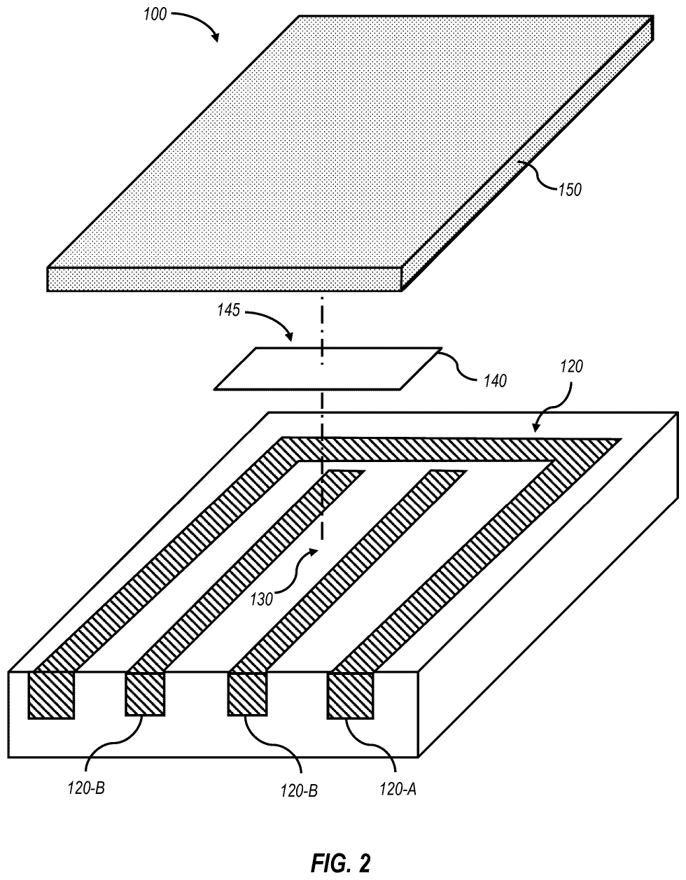

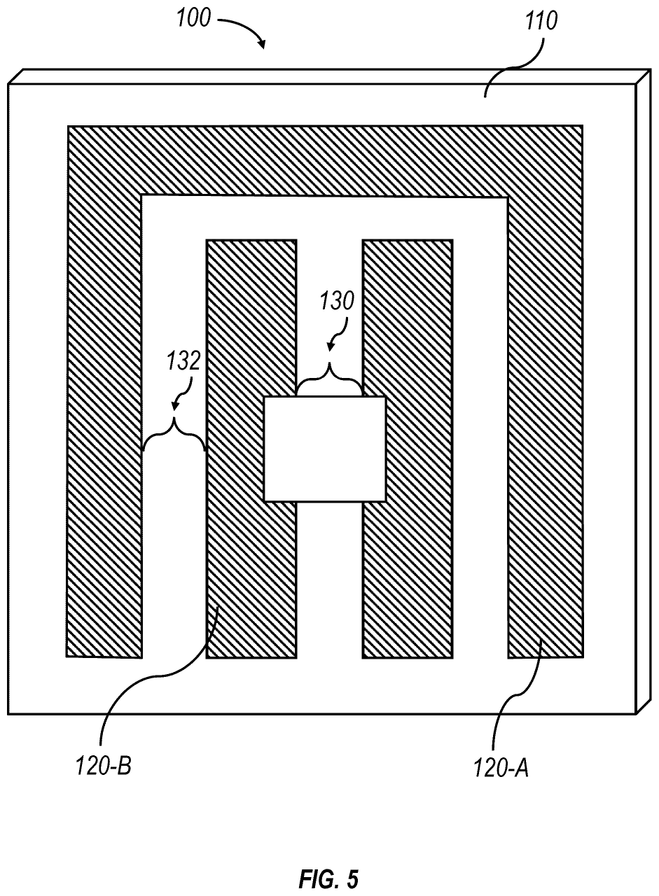

An example of a device for reversibly modulating electromagnetic radiation can be seen with reference to FIG. 1, FIG. 2 and FIG. 5. FIG. 1 shows a cross-sectional side-view of a device for reversibly modulating electromagnetic radiation (100). As shown, the device may include a base substrate (110). The base substrate may be a rigid or flexible material. A non-limiting example of the base substrate may include glass. Other non-limiting examples may include a metallic material (e.g., aluminum). In other examples, the base substrate may be a thermoplastic elastomer or a thermoplastic polyurethane. Those skilled in the art and informed by the teachings herein may envision other suitable arrangements of a base substrate. Additionally, although the base substrate is shown as being substantially rectangular, those skilled in the art will appreciate that the base substrate may be any suitable shape.

Referring briefly to FIG. 2, an exploded view of the device is shown. The device may include a patterned metal layer (120) disposed over the base substrate. The patterned metal layer may include a plurality of electrodes (120-B) separated by a gap (130) and at least one additional metal pattern (120-A) separated from the plurality of electrodes. The gap (130) may define an active area through which radiation is passed.

The electrodes may be independently comprised of any appropriate conductive material, including a metal, an alloy, an electrically conductive compound, or a combination thereof. The electrodes may be a single layer of a conductive material. Specific examples of such electrode materials may include gold, copper, silver, aluminum, chromium, sodium, sodium-potassium alloy, magnesium, lithium, magnesium/copper mixtures, magnesium/silver mixtures, magnesium/aluminum mixtures, magnesium/indium mixtures, rare earth metals, and the like. Specific examples also include heavily doped metal oxides such as indium tin oxide (ITO), fluorinated tin oxide (FTO), or aluminum zinc oxide (AZO). Preferably, the electrodes are configured to have some degree of flexibility/non-rigidness.

In FIGS. 1, 2, and 5 the plurality of electrodes (120-B) is shown as being substantially rectangular, however, those skilled in the art and informed by the teachings herein will recognize that other configurations are possible. For example, the plurality of electrodes may be substantially circular, triangular, trapezoidal, or any other suitable shape. Additionally, at least one of the plurality of electrodes may be a different shape than another electrode. For example, while one electrode may be substantially rectangular, other electrodes may be substantially circular or trapezoidal. Likewise, the at least one additional metal pattern (120-A) is shown as being substantially U-shaped, but those skilled in the art will appreciate that other configurations are also possible.

The device may include one or more porous or incomplete metal electrodes. The porous or incomplete metal electrodes may include voids or gaps defining one or more active areas through which radiation is passed.

Referring back to FIG. 1, the device may include an organic layer (140) disposed over at least the plurality of electrodes (120-B) and/or the one or more porous or incomplete metal electrodes, and base substrate (110), and within the gap (130). The organic layer (140) may include a conducting material (e.g., a polymer). The device may include an ion gel layer (150) disposed over the conducting material, the patterned metal layer (120) (see FIG. 2), and the base substrate (110).

Still referring to FIG. 1, the device may be configured to allow ions (210) from the ion gel layer to transport into the conducting material, doping or de-doping the organic layer, when a voltage is applied to at least one electrode of the plurality of electrodes.

In some embodiments, the conducting material may be a conjugated organic material, such as a conducting polymer. The conducting polymer may be a conducting polythiophene. The conducting polythiophene may be PEDOT:PSS. The conducting polythiophene may be pgBTTT. While PEDOT:PSS and pgBTTT are two examples of suitable conducting polythiophenes, those skilled in the art and informed by the teachings herein will appreciate that other suitable polythiophenes could be utilized, including, for example, PEDOT: Tosylate (PEDOT:Tos), PANI:PSS, PPy:PSS, PEDOT:PEG, and p(g2T-TT).

The conducting polymer is not limited to polythiophenes, rather the conducting polymer may include, as a non-exclusive list, polyacetylene, polyaniline, polypyrrole, poly(p-phenylene) (PPP), poly(phenylene vinylene) (PPV), polyfluorene, and poly(3-hexylthiophene).

In some embodiments, the conducting material may be a conducting small molecular weight organic material.

Still referring to FIG. 1, in some embodiments, the patterned metal may have a thickness (122) of at least 1 nm. The patterned metal may have a thickness of at least 10 nm. The patterned metal may have a thickness of at least 25 nm. The patterned metal may have a thickness of at least 50 nm. The patterned metal may have a thickness of at least 100 nm.

In some embodiments, the patterned metal may have a thickness (122) between about 10 nm-1000 nm. The patterned metal may have a thickness between about 25 nm-750 nm. The patterned metal may have a thickness between about 50 nm-500 nm. The patterned metal may have a thickness between about 100 nm-250 nm. The patterned metal may have a thickness between about 150 nm-200 nm.

Referring now to FIG. 2, in some embodiments, the active area (145) may be about 0.1 cm² in cross-sectional area in a plane parallel to a surface of the patterned metal layer. The active area may be at least 0.15 cm² in a plane parallel to a surface of the patterned metal layer. The active area may be at least 0.20 cm² in a plane parallel to a surface of the patterned metal layer. The active area may be at least 0.25 cm² in a plane parallel to a surface of the patterned metal layer. The active area may be at least 0.30 cm² in a plane parallel to a surface of the patterned metal layer. The active area may be at least 0.50 cm² in a plane parallel to a surface of the patterned metal layer. The active area may be at least 0.75 cm² in a plane parallel to a surface of the patterned metal layer.

In some embodiments, the active area (145) may be between about 0.10-0.75 cm² in cross-sectional area in a plane parallel to a surface of the patterned metal layer. The active area may be between about 0.25-0.50 cm² in cross-sectional area in a plane parallel to a surface of the patterned metal layer. The active area may be between about 0.30-0.40 cm² in cross-sectional area in a plane parallel to a surface of the patterned metal layer.

Referring briefly to FIG. 5, the space between the plurality of electrodes (120-B) and the least one additional metal pattern (120-A) may define a second gap (132). In some embodiments, the second gap may be larger than the gap (130) (“first gap”). For example, the second gap may be twice the size of the first gap. The second gap may be three times the size of the first gap. The second gap may be four times the size of the first gap.

In some embodiments, the second gap may be smaller than the first gap. In some embodiments, the second gap may be half the size of the first gap. The second gap may be a third of the size of the first gap. The second gap may be a quarter of the size of the first gap. In some embodiments, the second gap and first gap may be about the same size.

In some embodiments, the one or more porous or incomplete metal electrodes may include one or more metal nanowire meshes.

In various aspects, a system may be provided. The system may include a device for reversibly modulating electromagnetic radiation as described herein. The system may also include a detector disposed along a transmission path of one or more wavelengths of radiation from a radiation source through the active area of the device to the detector.

The system may further include the radiation source. The radiation source may include a gyrotron, backward wave oscillator, far-infrared laser, quantum cascade laser, or free-electron laser, synchrotron light source. The radiation source may also include a photoconductive antenna, Auston switch, or blackbody emitter.

The system may further include a controller operably coupled to the device. The controller may be configured to control application of a voltage to the device. Specifically, the controller may include one or more processors configured to control application of voltage, orientation of the device, or timing of modulation cycles.

In some embodiments, when a voltage is applied to the device, the voltage may be constant. In some embodiments, the voltage may vary over time. The voltage may be repeatedly switched between each of the plurality of electrodes.

In some embodiments, polarity of an applied gate voltage may be periodically reversed.

In some embodiments, the detector may be configured to measure at least one THz wavelength of radiation. The at least one THz wavelength of radiation may be measured in a direction normal to a surface of the patterned metal layer.

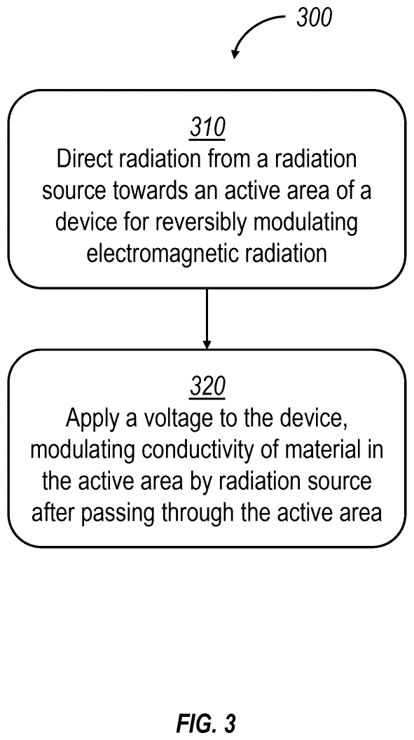

Referring now to FIG. 3, a flow diagram of a method (300) for reversibly modulating electromagnetic radiation is shown. The method may include directing (310) radiation from a radiation source towards an active area of a device as described herein. The method may include applying (320) a voltage to the device, modulating conductivity of material in the active area by radiation source after passing through the active area.

In some embodiments, the change may be an increase in power of the radiation at one or more wavelengths relative to the power of radiation prior to passing through the active area. In some embodiments, the change may be a decrease in power of the radiation at one or more wavelengths relative to the power of radiation prior to passing through the active area.

With the above-described devices, one can achieve significant transmission modulation over 87.5% (or 9 dB) from just a single layer of a mixed ionic-electronic conductive material. The device consists of an OMIEC channel that is dynamically “de-doped” in response to an external bias applied to an ion gel electrolyte. Demonstrated below is operation in both depletion and accumulation mode, switching between a conductive—THz damping—state and a non-conductive—THz transmissive—state. Demonstrated also is the connection of this behavior to optical switching, verifying the electrochromic behavior of the devices and their multispectral character across DC, THz, and optical regimes.

### Results and Discussion

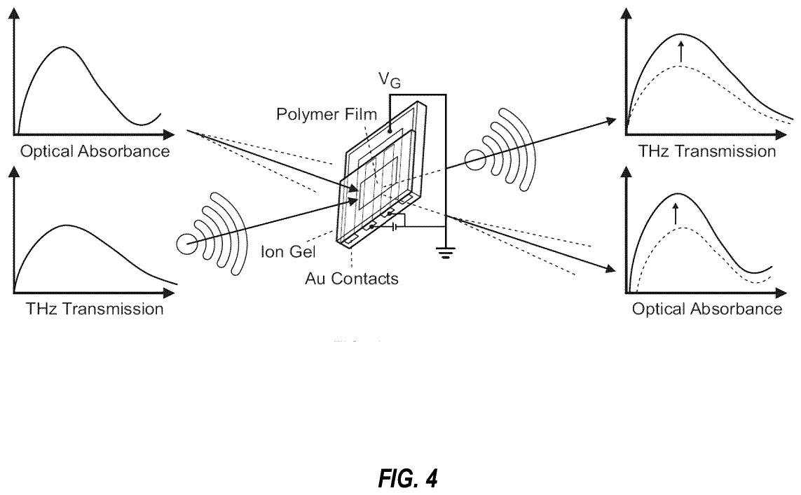

FIG. 4 shows schematics of the measurement setup for concurrent, in operando measurement of DC conductivity, THz, and ultraviolet-visible-near-infrared (UV-vis-NIR) optical switching. Referring back to FIG. 1, upon application of a gate voltage (V_{g}), mobile ions in the electrolyte enter the polymer channel layer, modulating the conductivity of the film. When a concurrent bias is applied to the two inner contacts transverse to the gate as displayed in FIG. 4 and FIG. 5, a current is induced to monitor conductivity, akin to traditional OECT operation. The broadband THz radiation is measured normal to the DC channel conduction, while the visible light probed at 632 nm is measured through a small spot size (≤1 mm) on the channel material at a 45° angle. FIG. 1 shows an example depletion mode OECT, with a positive gate bias causing the reduction of the PEDOT phases due to the PSS anions pairing with injected cations, leading to increased THz transmission. An accumulation mode device with a poly(2-(4,4′-bis(2-methoxyethoxy)-5′-methyl-[2,2′-bithiophen]-5-methylthieno [3,2-b]thiophene) pgBTTT channel layer operates by injection of anions into the thin film, leading to the stabilization of holes along the backbone. For the work, this polymer is chosen for its increased transconductance, hole mobility, and specific capacitance compared to other glycolated polythiophenes. In both cases, reversing the polarity of the applied gate voltage leads to the ejection of “counterions” in the bulk of the material, resetting the conductivity to near its initial value. FIG. 5 shows an embodiment of a sample device (the ion gel layer is omitted from FIG. 5 for clarity). Utilized is a three-terminal, bottom gate, and bottom contact device, where the gate is coplanar with the source and drain electrodes. For OECT operation, the gate bias is applied to the at least one additional metal pattern (120-A) (e.g., outer gold contact), while the DC (e.g., source to drain) conductivity is measured between the plurality of electrodes (120-B) (e.g., two inner contacts). For lone THz measurements, one grounds the two inner contacts to the same potential to operate as a two-terminal device, with a gate voltage on the outer contact providing the impetus for ions to flow into the OMIEC.

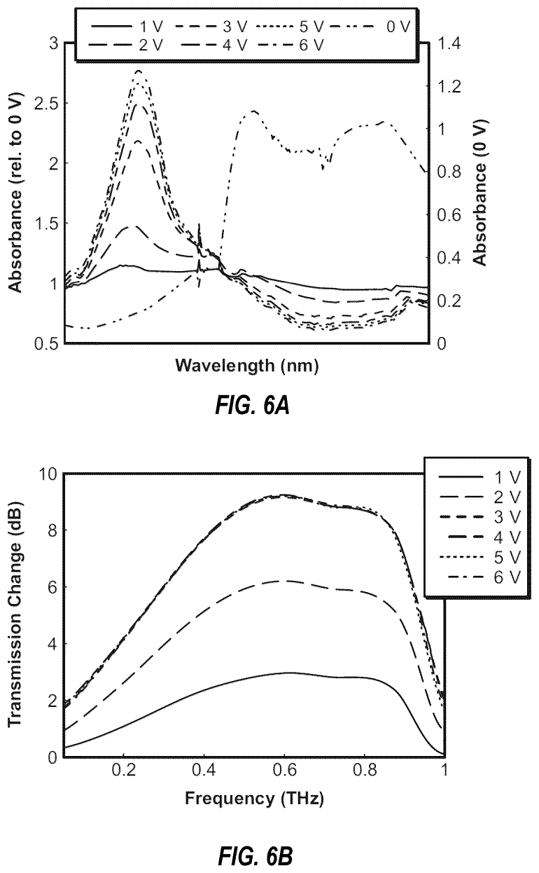

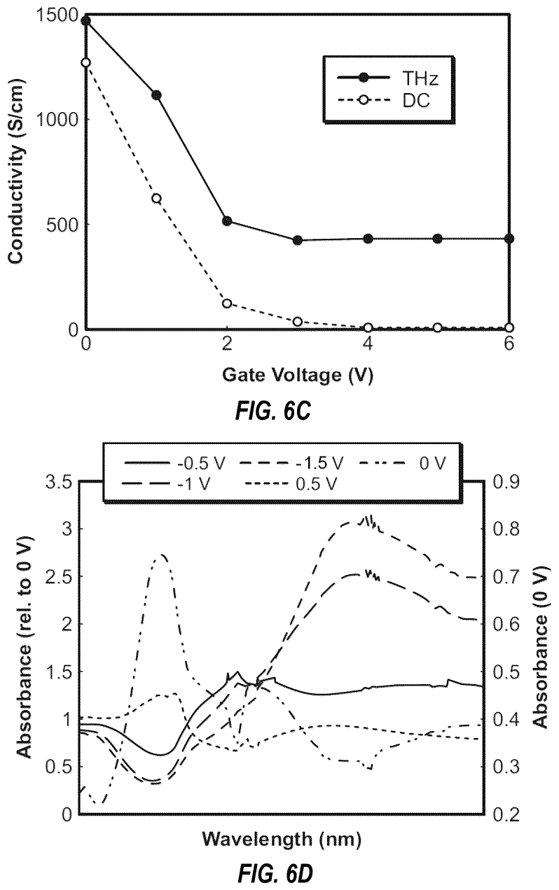

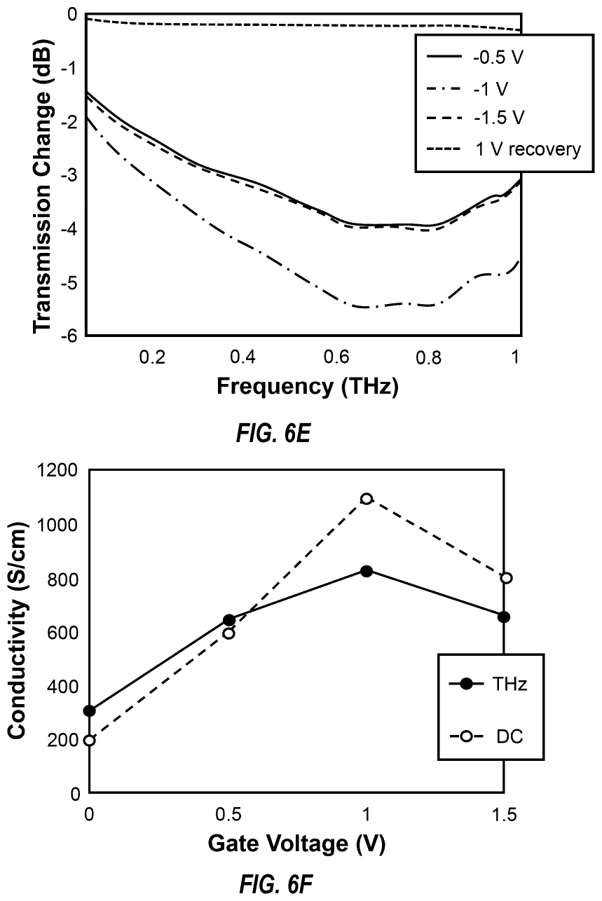

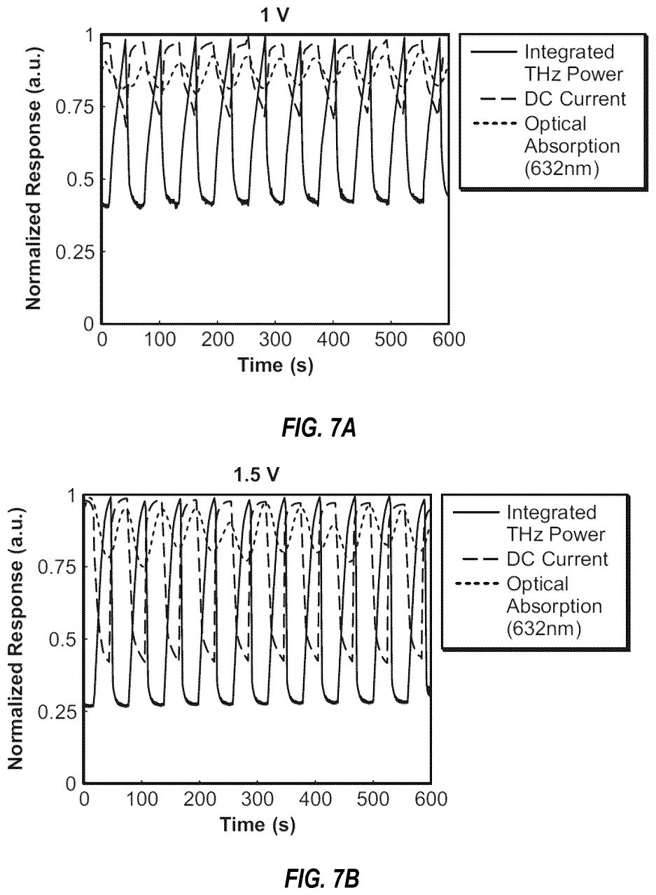

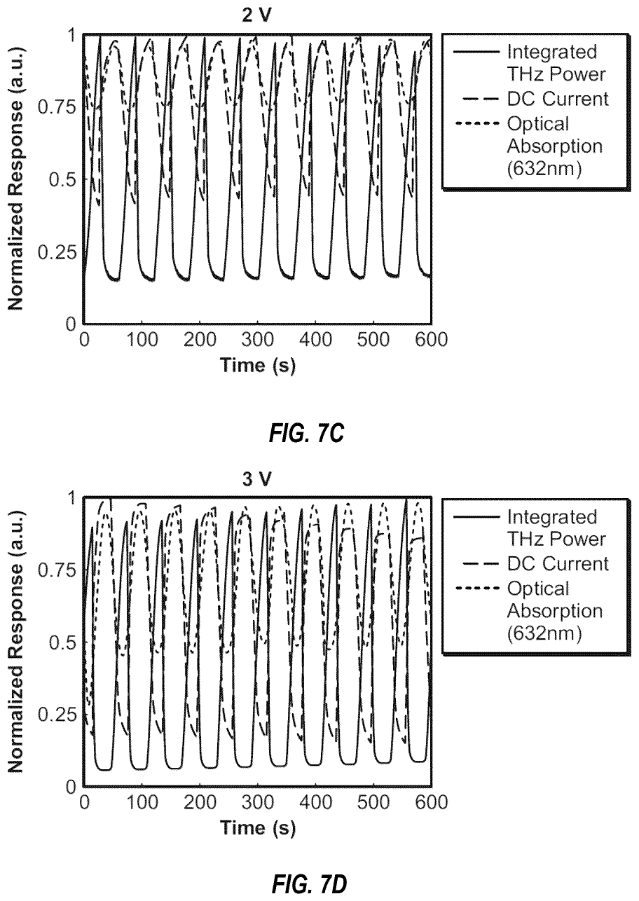

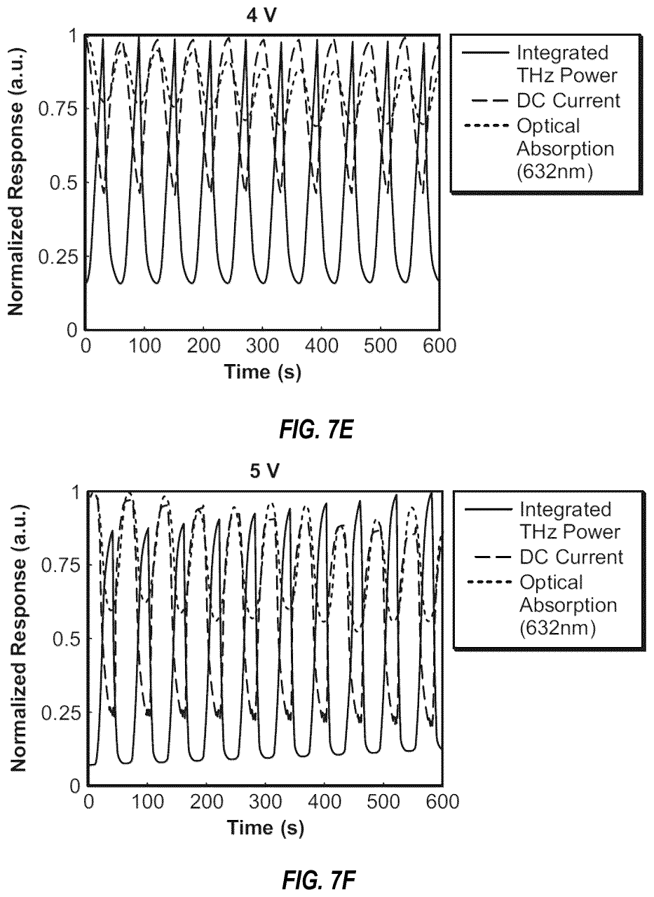

FIG. 6A and FIG. 6D present static spectroelectrochemical, THz, and DC measurements of depletion and accumulation mode devices, respectively. As the channel of the depletion mode device becomes de-doped by injection of EIM cations into the bulk, the DC conductivity of the PEDOT:PSS channel drops as the PSS anion is compensated. This reaction is known to occur per the following equation

$${PEDOT}^{+} {PSS}^{-} + {EIM}^{+} + {e}^{-} ⇌ {PEDOT}^{0} + {PSS}^{-} {EIM}^{+}$$

This reaction occurs with a bipolaronic (or polaron pair) component as well, the nature of which is still under debate. The structural changes that accompany the reduction of polaronic and bipolaronic PEDOT into neutral species are responsible for the change in conductivity and color of the channel layer. The neutral PEDOT phase is known to have an absorption peak at 660 nm, with the polaronic component at a wavelength of ˜1000 nm and an additional bipolaronic component at 1700 nm. As can be seen in FIG. 6A, an increase in the absorbance of the channel clearly occurs at 660 nm, corresponding to increased concentration of neutral PEDOT. A corresponding decrease in the polaronic and bipolaronic absorption is observed at approximately 1000 nm and 1700 nm, respectively, demonstrating the expected electrochromic behavior. Also observed is analogous behavior in the absorbance of the pgBTTT devices operating in accumulation mode in FIG. 6D. The neutral phase absorption at ˜600 nm is suppressed upon application of a reverse bias to the device, with a corresponding absorbance increase in the NIR associated with polarons and increased electrical conductivity.

In conjunction with the UV-VIS-NIR absorption changes induced by V_{g}, the THz transmission change is demonstrated in FIG. 6B and FIG. 6E. The increase in THz transmission of the PEDOT:PSS films is illustrative of depletion mode behavior, while the decrease in the pgBTTT films demonstrates accumulation mode behavior. Thus, both modes of operation are available for THz modulators, allowing for future application of complementary logic/operation. The static optical and THz measurements show increasing modulation with increasing voltage for PEDOT:PSS, a phenomenon verified in the DC conductivity changes discussed below. However, it's noted that the pgBTTT films appear to be less stable under higher biases, as demonstrated by the decrease of THz transmission when compared to 1 V.

In FIG. 6C and FIG. 6F, demonstrated is close correlation between the conductivity derived from the change in THz transmission with measured DC conductivity, confirming that charge carriers are responsible for the THz damping. In the absence of lattice contributions due to vibrational modes that often exist in the THz regime, the transmission of a highly conductive thin film can be found via the simple, closed-form expression:

$$T ( ω ) = \frac{2}{2 + id σ {Z}_{0}} , \qquad ( 1 )$$

where T is the ratio of the transmitted THz power to the incident THz power, ω is the frequency, d is the thickness of the semiconducting material, ψ its conductivity, and Z₀ is the characteristic impedance of free space, 377Ω. For these purposes, utilized is the integrated THz power from 0 to 1 THz as representative of the average ratio of received THz power to incident THz power. This equation holds for films of negligible optical thickness as used for the disclosed channel layers at the operating frequencies. Further, the DC conductivity of a semiconducting thin film is simply derived from the equation

$$R = ρ \frac{L}{A} , \qquad ( 2 )$$

where ρ=1/σ is the DC resistivity, L is the channel length, and A is the cross-sectional area (e.g., the product of the film thickness and the channel width). FIG. 6C and FIG. 6F show the correlation in behavior of the THz and DC conductivity calculated for both depletion and accumulation mode THz modulators. The small discrepancy in the THz vs. DC measurements is attributed to contact and parasitic resistance of the measurement setup. In summary, shown is close correlation of switching behavior across all three spectral domains, verifying the broadband and characteristic multispectral response of the devices.

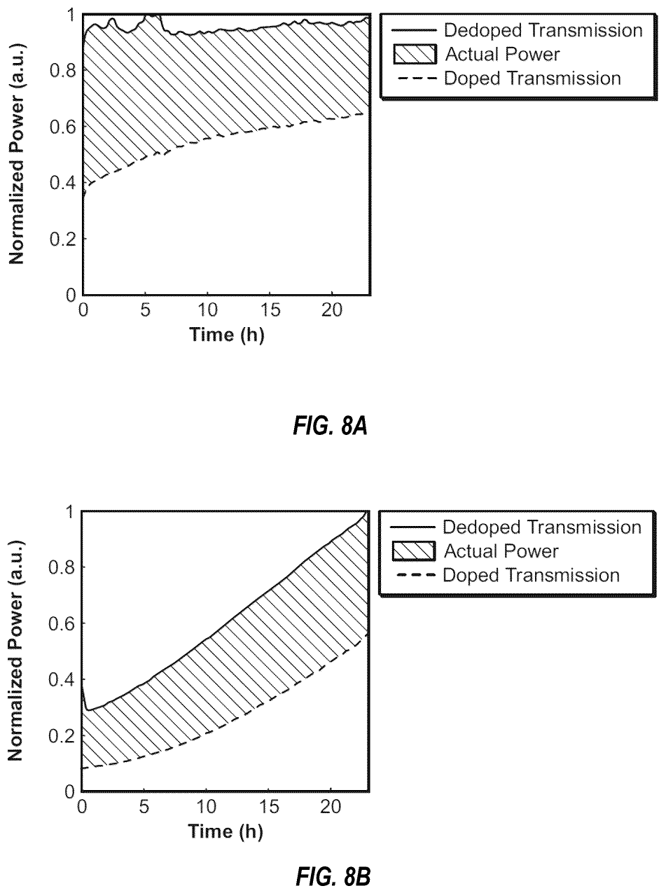

The operation and behavior of depletion mode devices are presented in FIGS. 7A-7F, FIGS. 8A-8C, and FIGS. 9A-9B. Focused on here is the multispectral, continuous switching of devices as the long-term stability under extended operation. FIGS. 7A-7F demonstrate the close correlation of the DC conductivity, THz, and visible absorption (at 632 nm) under differing input square wave gate voltages, all with 60 s periods and 50% duty cycle (i.e., 30 s ON/OFF durations). The reverse bias applied during the square wave was −1 V for all devices and was used to eject EIM cations from the PEDOT:PSS film and achieve faster recovery times. The flat-band response of the system demonstrated in FIG. 1 from 500 to 900 GHz is chosen as the integration region for calculating the total THz power. Observed is switchable absorption at voltages as low as 1 V, with an increasing trend in dynamic range at higher voltages. Additionally, all voltages at or above 1.5 V demonstrate the capability of ≥6 dB switchable absorption over 10 min.

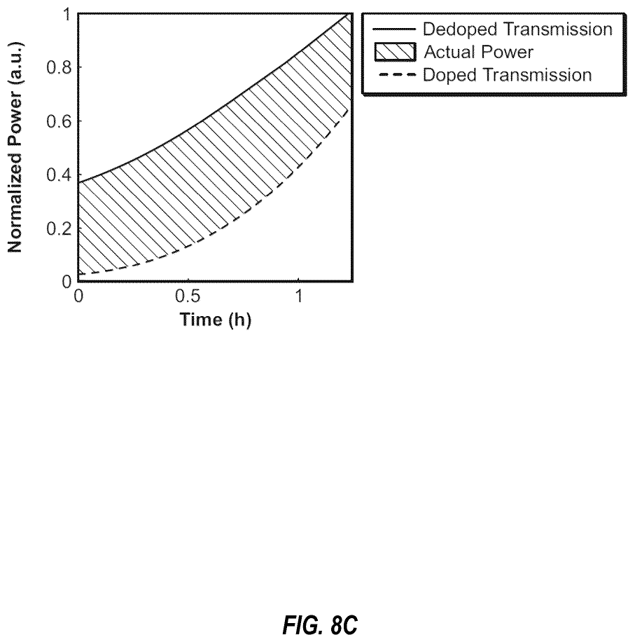

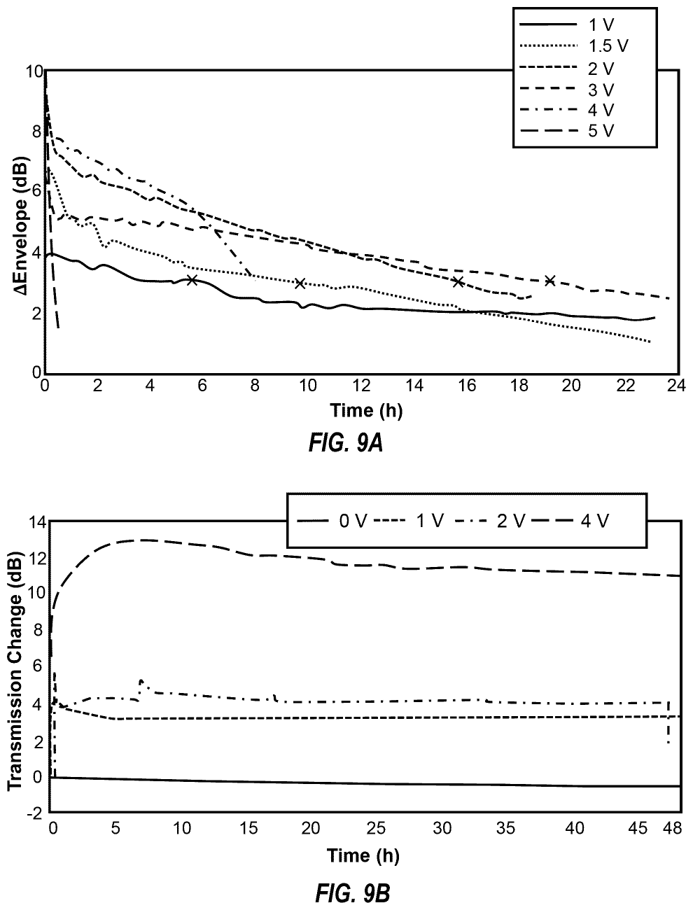

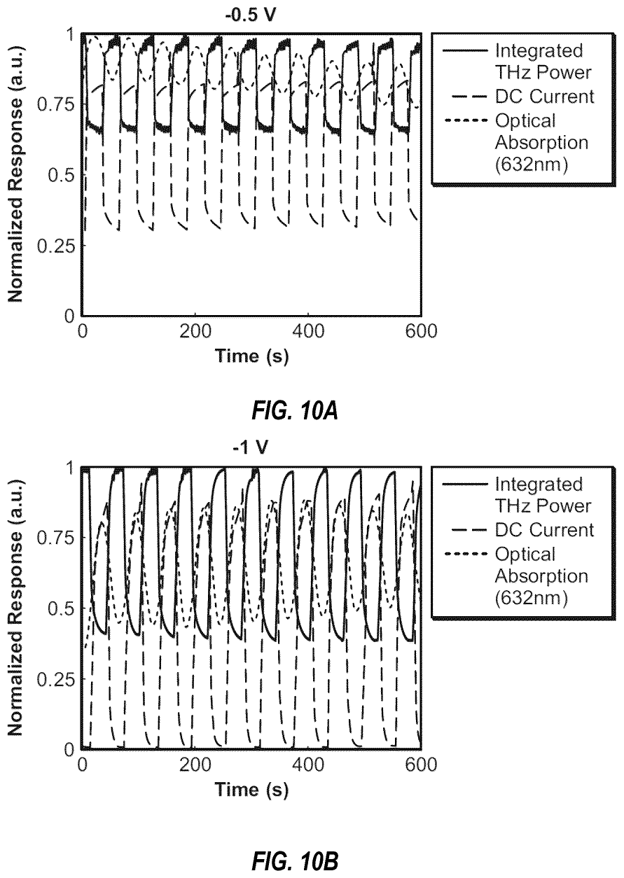

The simultaneous switching behavior discussed above also illustrates a key issue in the stability of these devices, namely the decrease in dynamic range of the THz transmission modulation in certain devices (devices at 3 and 5 V, specifically, in FIGS. 7A-7F) over 10 min, also demonstrated in the long-term measurements in FIGS. 8A-8C, and FIG. 9A. This is demonstrative of the key source of instability in the devices, a steady decrease in conductivity of the PEDOT:PSS films under repeated switching. In PEDOT:PSS, the PSS anion exists in the film to enhance solubility as well as provide a counter-ion to the PEDOT phases so that holes are stabilized in the backbone. However, the PSS anion itself is insulating, reducing the bulk conductivity of the channel material. The addition of a polar solvent (such as DMSO in the disclosed devices) greatly enhances the conductivity of the bulk material by reordering the morphology of the films such that longer, more aggregated PEDOT phases/crystallites exist, thus enhancing charge transport. It's posited that the repeated injection and ejection of cations into the PEDOT:PSS films and its associated swelling and contraction, along with the repeated reduction and oxidation of the channel material, could cause significant morphological changes and degradation over time. For example, the uptake of water in channel materials in OECTs and the resulting swelling of the films is a well-known phenomenon. If the morphology reverts to a more even distribution of PEDOT and PSS phases, the conductivity of the material overall would decay as observed in the long-term stability measurements. These lower conductivity films in turn reduce the dynamic range in the THz modulators. It's noted that the decay mechanism of the films is indicative of PEDOT:PSS becoming more insulating under repeated switching, with the final conductivity value similar to that of PEDOT:PSS films without DMSO treatment. This is studied further by conducting extended device operation over two days to investigate the long-term stability under constant switching as well as constant bias. FIGS. 8A-8C show the THz power over longer time periods for three representative voltages, V_{g}=1, 3, and 5 V, under continuous switching. There is a clear trend in THz transmission increasing over time, meaning a decrease in the overall conductivity of the film. This manifests as a decreased ability of the film to switch to a THz damping state with time, leading to a decreased dynamic range.

In order to assess long-term stability, defined is an upper and lower envelope signal (corresponding to the base, THz attenuating state, and the THz transmissive state achieved during cation injection) of the THz power over time and the difference of these envelopes is taken in a dB scale. Defined are two critical stability thresholds: the 6 and 3 dB points corresponding to 75% and 50% modulation depth respectively. FIG. 9A shows the resulting life-times for each device at different voltages. The device biased at 3 V exhibits a 3 dB threshold of ˜20 h. This voltage is attributed to being the most stable to the saturation of the THz response at 3 V evident in FIG. 1. In this scenario, 3 V achieves the maximum dynamic range in the device within its electrochemical stability window. There are a myriad of factors that determine the total THz absorption in both the attenuating and transmissive states that are challenging to rigorously control for, including the relationships between bias and total absorption, bias and rise times, the ability to completely recover from a doped state (e.g., fully eject ions from the film), and much more, that merit further study. However, a quick glance at the 3 V plot shows it appears to reside at a critical point of the slopes of the upper and lower envelopes, implying that the total difference between the doped and undoped states and their corresponding conductivities are well-matched, “balancing” each other well to achieve long-term stability. However, an increased voltage can provide additional dynamic range at the expense of stability, with 6 dB switchable absorption being possible for ˜5 h at 4 V. Additionally, it's been observed that higher voltage operation (particularly 5 V and above) leads to a rapid decline in performance, with many devices failing in less than an hour, putting a limit on the operating voltages achievable in the devices.

Beyond continuous switching, many applications in the areas of reconfigurable devices or sensors require operation under a constant bias for extended periods of time. This behavior is probed in FIG. 9B. Each bias point can be maintained for extended periods of time with little change, a promising feature for long-term reconfigurability of devices. FIG. 9B also demonstrates that significant change can be affected in the total THz absorption of the devices, with 4 V showing up to 95% absorption change when allowed to operate continuously at constant bias. This behavior is attributed to a more complete permeation of ions from the electrolyte throughout the entire bulk of the film, rather than a possibly ‘incomplete’ ion injection that occurs when the bias is reversed before a more complete diffusion of ions can occur. A key source of instability is also seen for the switching devices, namely the reverse bias used to ‘reset’ the conductivity of the films. When allowed to sit at this reverse bias, the device shows relatively rapid degradation of its conductivity. As mentioned above, a delicate balance of factors is at play-in order to achieve switching within a 30 s window, the reverse bias is required to more quickly eject cations from the film. However, this corresponds to a decreasing conductivity over time. It is evident that there exist optimal biasing protocols that can maximize dynamic range, stability, or find a more ideal tradeoff between the two figures of merit, that can be explored further depending on application.

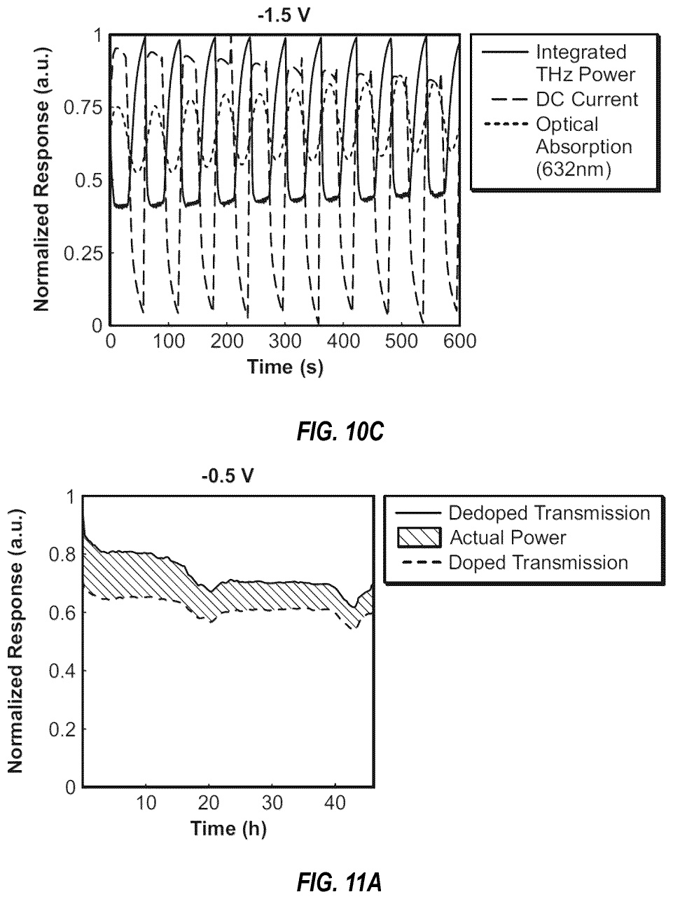

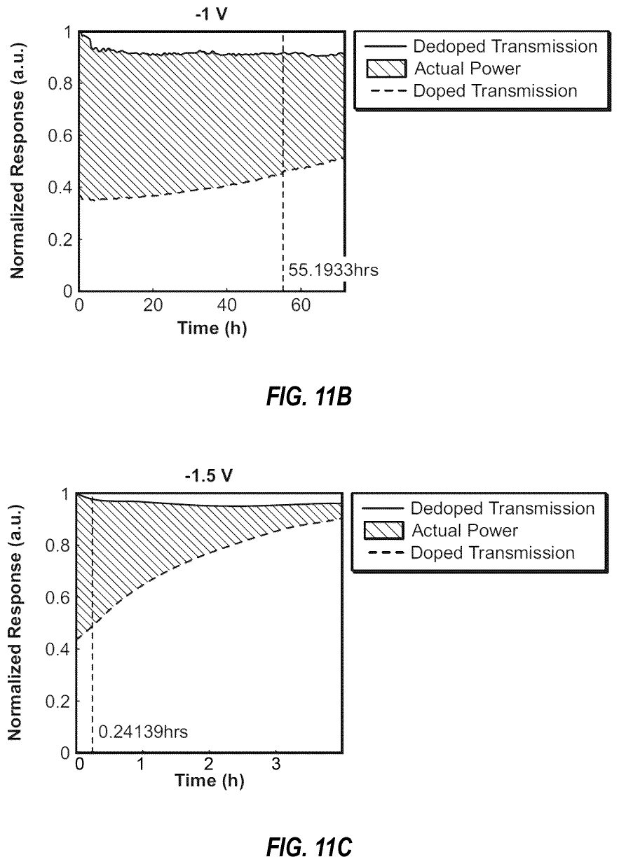

An important corollary of depletion mode device operation in OECTs is that of accumulation mode devices, where the channel material is normally insulating, or ‘OFF’, and becomes conducting upon application of a bias. This accumulation mode capability is demonstrated in FIGS. 10A-10C, FIGS. 11A-11C, and FIG. 12, using the polymer pgBTTT as the active layer. These devices operate with the gate electrode at a lower potential than the channel layer, implying injection of anions into the polymer film as the mechanism for conductivity changes. FIGS. 10A-10C illustrate the short-term switching behavior of the devices, while FIGS. 11A-11C show the long-term stability under continuous switching. Notably, pgBTTT shows enhanced stability when the applied bias is kept within an electrochemical stability window of the material, which is found to be roughly −1 V. Above this voltage, the devices rapidly degrade without the benefit of any clear additional dynamic range. However, when kept below this threshold the devices show impressive stability under continuous switching when compared to PEDOT:PSS. It's demonstrated over two-days long operation under continuous operation, nearly tripling that of the best depletion mode device. Hence the accumulation mode devices are capable of stable low-voltage operation, albeit within a narrower electrochemical stability window.

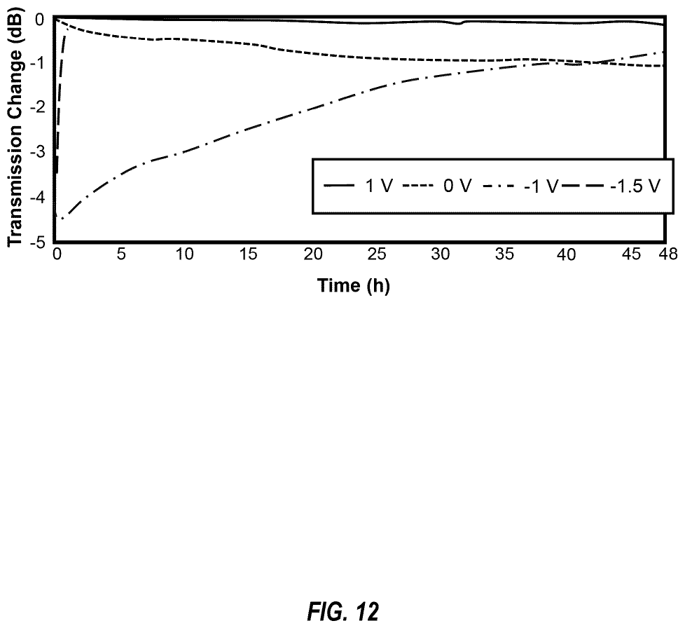

Finally, FIG. 12 shows the long-term stability of the pgBTTT devices under continuous bias (i.e., no switching). One can see the rapid degradation of the −1.5 V device, corroborated by its instability seen in the continuous switching behavior. Notably, the continuous bias on the device appears to degrade its conductivity in the “ON” state even in the stable voltage regime, behavior that is not replicated in the PEDOT:PSS devices. The −1 V bias achieves up to 4.5 dB when initially applied, but over two days the conductivity slowly approaches the “OFF” state, indiciative of an insulating channel layer. This suggests that accumulation mode devices based on pgBTTT would not be strong candidates for long-term reconfigurability, but would operate well for use cases where continuous switching (modulation, sensing, etc.) is required.

### Conclusion

Provided herein is a demonstration of the feasibility of organic electrochemical modulators in the THz regime and an evaluation of their multispectral switching behaviors (DC, THz, and optical), as well as their stability under continuous switching and constant bias. The devices show good agreement between all spectral regions observed, within corroborated conductivity calculations between DC and THz; spectroelectrochemistry measurements confirm the correspondence of the THz and visible spectrum electrochromism. Additionally demonstrated is both depletion and accumulation mode behavior, observing different stability behaviors. Depletion mode PEDOT:PSS devices show stability behaviors. Depletion mode PEDOT:PSS devices show stability under repeated switching greater than 10 h, while the accumulation mode pgBTTT devices can operate for over 2 days under repeated switching. These time periods, corresponding to over 1000 and 3000 cycles respectively are on par with, and in some cases exceeding, comparable OECT devices in literature. On the other hand, depletion mode devices show a high degree of stability over multiple days under a continuous bias, while their accumulation mode counterparts show degradation under similar conditions. Overall, this work indicates additional applications of conjugated polymer OMIECs and ECDs as electrochemical switches and modulators in the THz range, ranging from communication, reconfigurable waveguides, high bandwidth modulation, wireless sensing, bioelectronic devices, and more. Achieved is over 90% modulation depth from thin polymer films of a few hundred nanometers, and demonstrated is their reversibility and reconfigurability. It's anticipated that even greater modulation depths can readily be achieved with techniques that result in thicker films. Future work could explore increased modulation amplitude, causes of instability, and higher resolution patterning for wireless metasurfaces/metadevices, usage in flexible modulators, and many other potential applications.

### Methods

The free-standing ion gels were prepared according to conventional techniques. The ionic liquids were dried in a vacuum oven at 70° C. for 24 hours prior to mixing. The ion gel solution was prepared in a weight ratio of 17.6% ionic liquid, 4.4% p(VDF-HFP), and 78% acetone as solvent. The solutions were mixed overnight at 40° C. The resulting solution was then drop cast onto glass slides, and left to dry in a vacuum oven for 24 hours at 70° C. The resulting ion gel was solid at room temperature, cut from the glass slides, and transferred onto the device substrate.

The PEDOT:PSS solution was mixed with 10% by wt. dimethyl sulfoxide (DMSO) as a conductivity promoter and was used in depletion mode devices. The polymer poly(2-(4,4′-bis(2-methoxyethoxy)-5′-methyl-[2,2′-bithiophen]-5-yl)-5-methylthieno[3,2-b]thiophene (pgBTTT) used in enhancement mode devices was synthesized following past protocols and dissolved in chloroform at a 10 mg/mL concentration. 100 nm Au contacts were patterned using a shadow mask in a vacuum thermal evaporator, with a 2 nm Cr underlayer to promote adhesion. The polymers were then spin-coated onto the gold contacts at 300 rpm (yielding ˜500 nm PEDOT:PSS and ˜250 nm pgBTTT thick films), and wet-patterned to remove material from unwanted areas. The resulting active area was 0.6×0.6 cm. Following annealing of the polymer at 120° C. for 30 min (PEDOT:PSS) and 100° C. for 30 min (pgBTTT), the ion gel was transferred onto the THz device by hand and cut to fit the active area of the device.

### Measurements

The in-situ THz time-domain spectroscopy (THz-TDS) data were collected using a TeraMetrix T-Ray 5000 from Luna Innovations. The system captured a ˜12 ps pulse every 100 ms which was then Fourier-transformed to obtain the spectral data. For real-time modulation studies, the integrated power of this spectra was captured to show the changes in transmission. The integration bandwidth was chosen to be the flat-band region from 500-900 GHz as shown in FIG. 6B. The in-situ DC conductivity data was captured using a Keithley 2400 SourceMeter. A bias of ±100 mV was applied and the resulting current measured across the device area. This bias was repeatedly switched between the two interior contacts to avoid selective deprotonation of one side of the active region. The in-situ optical transmission data were captured using a ThorLabs DET10A1 Si photodetector, with a 632 nm laser module used as a source. The UV to visible absorption data were captured separately using a Cary 5000 UV-Vis.

Various modification may be made to the systems, methods, apparatus, mechanisms, techniques, and portions thereof described herein with respect to the various figures, such modifications being contemplated as being within the scope of the present disclosure. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modification and the like.

Although various embodiments which incorporate the teachings of the present disclosure have been shown and described in detail herein, those skilled in the art can readily devise many other varied embodiments that still incorporate these teachings. Thus, while the foregoing is directed to various embodiments of the present disclosure, other and further embodiments of the present disclosure may be devised without departing from the basic scope thereof. As such, the appropriate scope of the present disclosure is to be determined according to the claims.

What is claimed is:

1. A device for reversibly modulating electromagnetic radiation, comprising:
a base substrate;
a patterned metal layer disposed over the base substrate, the patterned metal layer including:
a plurality of electrodes separated by a gap and at least one additional metal pattern separated from the plurality of electrodes, the gap defining an active area through which radiation is passed; and/or
one or more porous or incomplete metal electrodes, where the porous or incomplete metal electrodes include voids or gaps defining one or more active areas through which radiation is passed;
an organic layer disposed over at least the plurality of electrodes, and/or the one or more porous or incomplete metal electrodes, and base substrate, and within the gap, the organic layer including a conducting material; and
an ion gel layer disposed over the conducting material, the patterned metal layer, and the base substrate; and
wherein the device is configured to allow ions from the ion gel layer to transport into the conducting material, doping or de-doping the organic layer, when a voltage is applied to at least one electrode of the plurality of electrodes.

2. The device of claim 1, wherein the conducting material comprises a conducting polymer.

3. The device of claim 1, wherein the conducting material comprises conducting small molecular weight organic material.

4. The device of claim 2, wherein the conducting polymer comprises a conducting polythiophene.

5. The device of claim 4, wherein the conducting polythiophene comprises PEDOT:PSS.

6. The device of claim 4, wherein the conducting polythiophene comprises pgBTTT.

7. The device of claim 1, wherein the patterned metal layer has a thickness of at least 50 nm.

8. The device of claim 7, wherein the patterned metal layer has a thickness of 50 nm-500 nm.

9. The device of claim 1, wherein the active area is at least 0.25 cm² in cross-sectional area in a plane parallel to a surface of the patterned metal layer.

10. The device of claim 1, wherein the active area is 0.25 cm²-0.5 cm² in cross-sectional area in a plane parallel to a surface of the patterned metal layer.

11. The device of claim 1, wherein the one or more porous or incomplete metal electrodes includes one or more metal nanowire meshes.

12. A system, comprising:
a device of claim 1; and
a detector disposed along a transmission path of one or more wavelengths of radiation from a radiation source through the active area of the device to the detector.

13. The system of claim 12, further comprising the radiation source.

14. The system of claim 12, further comprising a controller operably coupled to the device, the controller configured to control application of a voltage to the device.

15. The system of claim 12, wherein, when a voltage is applied to the device, the voltage is constant.

16. The system of claim 12, wherein, when a voltage is applied to the device, the voltage varies over time.

17. The system of claim 12, wherein, when a voltage is applied to the device, the voltage is repeatedly switched between each of the plurality of electrodes.

18. The system of claim 12, wherein polarity of an applied gate voltage is periodically reversed.

19. The system of claim 12, wherein the detector is configured to measure at least one THz wavelength of radiation.

20. The system of claim 19, wherein the at least one THz wavelength of radiation is measured in a direction normal to a surface of the organic layer.

21. A method for reversibly modulating electromagnetic radiation, comprising:
directing radiation from a radiation source towards an active area of a device of claim 1; and
applying a voltage to the device, modulating conductivity of material in the active area by radiation source after passing through the active area.

22. The method of claim 21, wherein the modulation is an increase in power of the radiation at one or more wavelengths relative to the power of radiation prior to passing through the active area.

23. The method of claim 21, wherein the modulation is a decrease in power of the radiation at one or more wavelengths relative to the power of radiation prior to passing through the active area.
